(19) United States
(12) Patent Application Publication
(10) Pub. No.: US 2013/0118549 A1
(43) Pub. Date: May 16, 2013

(54) SOLAR POWER CONCENTRATOR AND SOLAR POWER COLLECTING DEVICE USING SAME

(71) Applicant: LI-YING WANG HE, Tu-Cheng (TW)

(72) Inventor: LI-YING WANG HE, Tu-Cheng (TW)

(73) Assignee: HON HAI PRECISION INDUSTRY CO., LTD., Tu-Cheng (TW)

(21) Appl. No.: 13/551,555

(22) Filed: Jul. 17, 2012

(30) Foreign Application Priority Data
Nov. 10, 2011 (TW) 100140989

(51) Int. Cl. H01L 31/052; G02B 17/08

(52) U.S. Cl. 136/246; 359/728

(57) ABSTRACT

A solar power collecting device includes a solar power concentrator and a solar cell. The solar power concentrator includes a fructoconical reflector and a converging lens. The reflector includes a fructoconical inner reflecting surface, a wide end open to an outside and a narrow end, the reflecting surface configured for reflecting and directing sunlight from the wide end to the narrow end. The converging lens is located at the narrow end of the reflector, and is configured for receiving and converging the reflected sunlight from the reflector and sunlight incident thereon directly from the wide end. The solar cell is configured for converting the converged sunlight from the solar power concentrator into electricity.

### BACKGROUND

1. Technical Field

The present disclosure relates to a solar power concentrator and solar power collecting device using same.

2. Description of Related Art

A typical solar power collecting device for solar energy uses one or more convex lenses as concentrators for concentrating and converging sunlight to solar cells. However, such convex lenses are limited in the area exposed to sunlight, which may be insufficient to collect enough sunlight for the solar cells to produce a large electrical current.

What is needed, therefore, is a solar power concentrator and a solar power collecting device, which can overcome the above shortcomings.

### BRIEF DESCRIPTION OF THE DRAWINGS

Many aspects of the present solar power concentrator and solar power collecting device can be better understood with reference to the following drawings. The components in the drawings are not necessarily drawn to scale, the emphasis instead being placed upon clearly illustrating the principles of the present solar power concentrator and solar power collecting device. Moreover, in the drawings, like reference numerals designate corresponding parts throughout the several views.

FIG. 1 is a cross sectional view of a solar power collecting device in accordance with an embodiment, the solar power collecting device including a solar power concentrator and a solar cell.

FIG. 2 is a top plan view of the solar power concentrator of FIG. 1.

### DETAILED DESCRIPTION

Embodiments of the present solar power concentrator and solar power collecting device will be described with reference to the drawings.

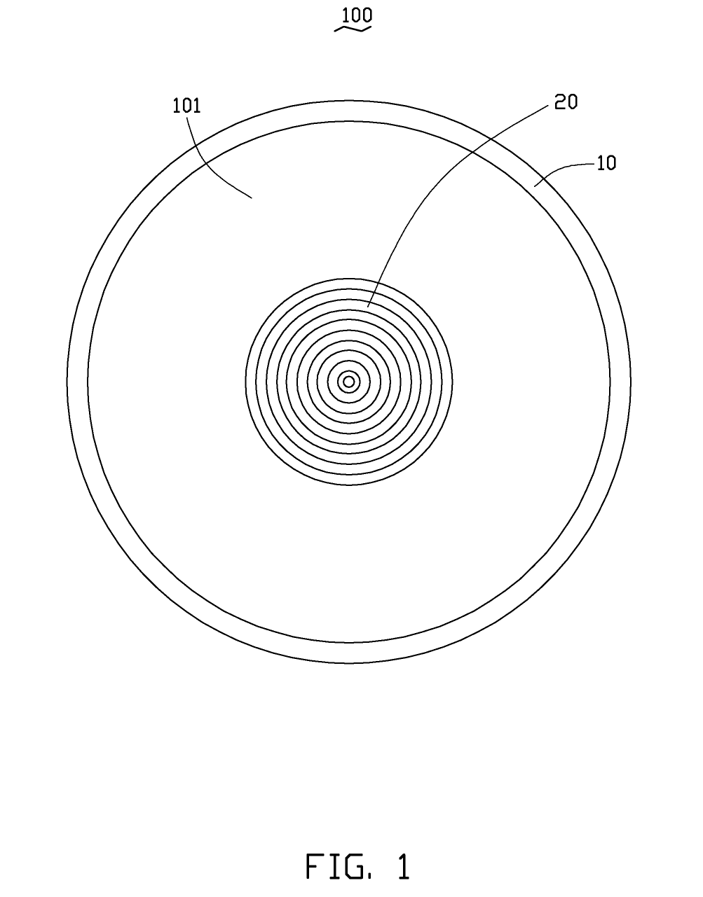

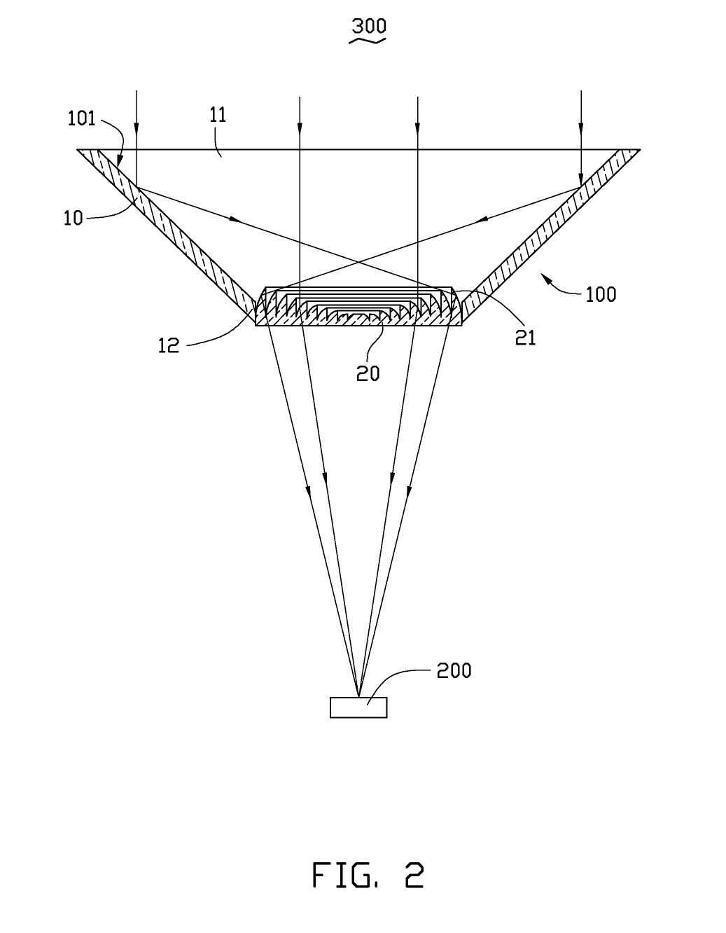

Referring to FIGS. 1 and 2, a solar power collecting device 300 includes a solar power concentrator 100, and a solar cell 200 placed under the solar power concentrator 100.

The solar power concentrator 100 includes a fructoconical reflector 10 and a converging lens 20. The reflector 10 includes a fructoconical inner reflecting surface 101, a wide end 11 open to an outside, and a narrow end 12 adjacent to the converging lens 20. A diameter of the reflector 10 increases dramatically from the narrow end 12 to the wide end 11, such that the entire inner peripheral reflecting surface 101 can be exposed to sunlight.

The converging lens 20 is located at the narrow end 12 of the reflector 10, and converges sunlight to the solar cell 200. In the present embodiment, the converging lens 20 is a Fresnel lens which has a plurality of Fresnel-zones 21 arranged in a pattern of concentric circles on the top surface. In other embodiments, the converging lens 20 may be convex.

The reflector 10 has a large area for reflecting sunlight onto the converging lens 20. That is, the converging lens 20 not only receives incident sunlight directly from the wide end 11, but also receives the reflected sunlight from the reflector 10. In this way, the total quantity of sunlight the solar power concentrator 100 received and which can be gathered by the solar power collecting device 300 is increased. In the present embodiment, the reflector 10 and the converging lens 20 are unitarily formed, i.e., the solar power concentrator 100 is an integral piece, which makes the solar power concentrator 100 compact.

The solar cell 200 receives the converged sunlight from the solar power concentrator 100, and converts the sunlight into electricity. The solar cell 200 may include semiconductor layers to convert sunlight into electricity. As the sunlight is concentrated by the solar power concentrator 100, the surface area of the solar cell 200 can be reduced or the performance of the solar power collecting device 300 will be enhanced with the surface area of the solar cell 200 of related art.

It is understood that the above-described embodiments are intended to illustrate rather than limit the disclosure. Variations may be made to the embodiments and methods without departing from the spirit of the disclosure. Accordingly, it is appropriate that the appended claims be construed broadly and in a manner consistent with the scope of the disclosure.

What is claimed is:

1. A solar power concentrator, comprising:
a fructoconical reflector comprising a fructoconical inner reflecting surface, a wide end open to an outside and a narrow end, the reflecting surface configured for reflecting and directing sunlight from the wide end to the narrow end; and
a converging lens located at the narrow end of the reflector, the converging lens configured for receiving and converging the reflected sunlight from the reflector and sunlight incident thereon directly from the wide end.

2. The solar power concentrator of claim 1, wherein the reflector and the converging lens are unitarily formed.

3. The solar power concentrator of claim 1, wherein the reflector surrounds the converging lens.

4. The solar power concentrator of claim 1, wherein the converging lens is a Fresnel lens.

5. The solar power concentrator of claim 1, wherein the converging lens is a convex lens.

6. A solar power collecting device, comprising:
a solar power concentrator comprising:
a fructoconical reflector comprising a fructoconical inner reflecting surface, a wide end open to an outside and a narrow end, the reflecting surface configured for reflecting and directing sunlight from the wide end to the narrow end; and
a converging lens located at the narrow end of the reflector, the converging lens configured for receiving and converging the reflected sunlight from the reflector and sunlight incident thereon directly from the wide end; and
a solar cell configured for receiving and converting the converged sunlight from the solar power concentrator into electricity.

7. The solar power collecting device of claim 6, wherein the reflector and the converging lens are unitarily formed.

8. The solar power collecting device of claim 6, wherein the reflector surrounds the converging lens.

9. The solar power collecting device of claim 6, wherein the converging lens is a Fresnel lens.

10. The solar power collecting device of claim 6, wherein the converging lens is a convex lens.

11. The solar power collecting device of claim 6, wherein the solar cell comprises semiconductor layers to convert the converged sunlight into electricity.
